(19) United States
(12) Patent Application Publication
(10) Pub. No.: US 2026/0269712 A1
(43) Pub. Date: Sep. 10, 2026

(54) ACTIVE SHORT CIRCUIT OVERCURRENT DETECTION

(71) Applicant: Caterpillar Inc., Peoria, IL (US)

(72) Inventors: John Edmund Young, East Peoria, IL (US); Venkata Ramakrishna Challa, Narasaraopet (IN); Ponkamali Paramasvivan, Coimbatore (IN)

(73) Assignee: Caterpillar Inc., Peoria, IL (US)

(21) Appl. No.: 19/071,010

(22) Filed: Mar. 5, 2025

(51) Int. Cl. H02M 1/088; G01R 31/34; H02M 1/00; H02M 1/084; H02M 1/32; H02M 7/5395; H02P 6/182; H03K 17/0812

(52) U.S. Cl. CPC H02M 1/088; G01R 31/343; H02M 1/0009; H02M 1/084; H02M 1/32; H02M 7/5395; H02P 6/182; H03K 17/08128

(57) ABSTRACT

A switching inverter circuit for an electric motor includes top IGBTs and bottom IGBTs configured to provide energy to the electric motor, an overcurrent detection circuit, and an inverter controller. The inverter controller is configured to produce gate drive signals to switch the top IGBTs and bottom IGBTs according to a first operating mode; disable the gate drive signals in response to the overcurrent detection circuit detecting overcurrent that exceeds a first overcurrent threshold in the first operating mode; produce gate drive signals to activate one of all the top IGBTs or all the bottom IGBTs in an Active Short Circuit (ASC) mode; and disable the gate drive signals to the IGBTs of the inverter circuit in response to the overcurrent detection circuit detecting an overcurrent level that exceeds a second overcurrent detection threshold greater than the first overcurrent detection threshold.

### TECHNICAL FIELD

This document relates to electric powered work machines and in particular to techniques to improve performance and safety of the electric motors of electric work machines.

### BACKGROUND

Electric powered large moving work machines (e.g., wheel loaders, mining trucks, etc.) use large capacity energy sources to drive one or more electric motors. Back electromotive force (EMF), also known as counter-electromotive force, is a phenomenon that occurs in electric motors and generators. EMF can include an induced voltage that opposes the primary voltage applied to an electric motor or generator. In electric motors, back-EMF is created when the motor's armature rotates in the magnetic field. As the armature coils move through this field, they generate a voltage according to Faraday's law of induction. This induced voltage opposes the applied voltage that is driving the motor, hence the term "back" or "counter" EMF. Back-EMF limits the motor’s speed. In a back-EMF failure mode, the speed control system of the electric motor fails and the loss of speed control can cause freewheeling current to occur. The freewheeling current can cause regenerative effects, such as charging a direct current (DC) bus above a maximum allowable voltage. Great Britain Patent No. GB 2,564,701 relates to a power electronics module that protects a solid state switching device in the event of a short circuit fault.

### SUMMARY OF THE INVENTION

Large electric powered work machines can include high current and voltage electric motors. Electrical circuits for the work machines include high power converter circuits that convert the DC energy from the energy source to AC energy to power the electric motors of a work machine. In the event of a failure or fault in a high power electric motor, it is desired to minimize damage to equipment of the work machine.

An example switching inverter circuit for an electric motor includes top insulated gate bipolar transistors (IGBTs) and bottom IGBTs configured to provide energy to the electric motor, an overcurrent detection circuit, and an inverter controller. The inverter controller is configured to produce gate drive signals to switch the top IGBTs and bottom IGBTs according to a first operating mode; disable the gate drive signals in response to the overcurrent detection circuit detecting overcurrent that exceeds a first overcurrent threshold in the first operating mode; produce gate drive signals to activate one of all the top IGBTs or all the bottom IGBTs in an Active Short Circuit (ASC) mode when a back electromotive force (back-EMF) failure is detected; and disable the gate drive signals to the IGBTs of the inverter circuit in response to the overcurrent detection circuit detecting an overcurrent level that exceeds a second overcurrent detection threshold greater than the first overcurrent detection threshold.

An example method of operating a switching inverter circuit of an electric motor includes activating, in a first operating mode, gate drive signals to IGBTs of the inverter circuit to provide electrical energy to the electric motor; activating, in an ASC mode, the gate drive signals to one of a top set of the IGBTs of the switching inverter circuit or a bottom set of the IGBTs of the switching inverter circuit when detecting a back-EMF failure of the electric motor; disabling the gate drive signals to the IGBTs of the switching inverter circuit in the first operating mode when detecting overcurrent using a first overcurrent detection threshold; and disabling the gate drive signals to the IGBTs of the switching inverter circuit in the ASC mode when detecting overcurrent using a second overcurrent detection threshold greater than the first overcurrent detection threshold.

An example fault-detection circuit for a switching inverter circuit of an electric motor includes an overcurrent detection circuit, a back electromotive force (back-EMF) failure detection circuit, and a control circuit. The control circuit includes logic circuitry configured to disable gate drive signals produced by the switching inverter circuit in response to the overcurrent detection circuit detecting overcurrent that exceeds an overcurrent detection threshold of a first current value, wherein the gate drive signals IGBTs that provide power to the electric motor; and enable gate drive signals to activate one of a top set of IGBTs or a bottom set of IGBTs in an Active Short Circuit (ASC) mode in response to detection of a back-EMF failure and change the overcurrent detection threshold to a second current value greater than the first current value when in the ASC mode.

### BRIEF DESCRIPTION OF THE DRAWINGS

FIG. 1 is an elevation view depicting an example work machine in accordance with this disclosure.

FIG. 2 is a circuit diagram of an example of portions of a switching inverter circuit and an electric motor in accordance with this disclosure.

FIG. 3 is a graph of root-mean-square current versus rotor speed for an electric motor in accordance with this disclosure.

FIG. 4 is a circuit diagram of an example of an inverter circuit operating in Active Short Circuit mode in accordance with this disclosure.

FIG. 5 is an illustration of examples of phase current transients for the circuit diagram of FIG. 4 in accordance with this disclosure.

FIG. 6 is a flow diagram of an example of a method of operating a switching inverter circuit of an electric motor in accordance with this disclosure.

### DETAILED DESCRIPTION

Examples according to this disclosure are directed to electric circuits and methods that detect faults in operation of high output electric motors.

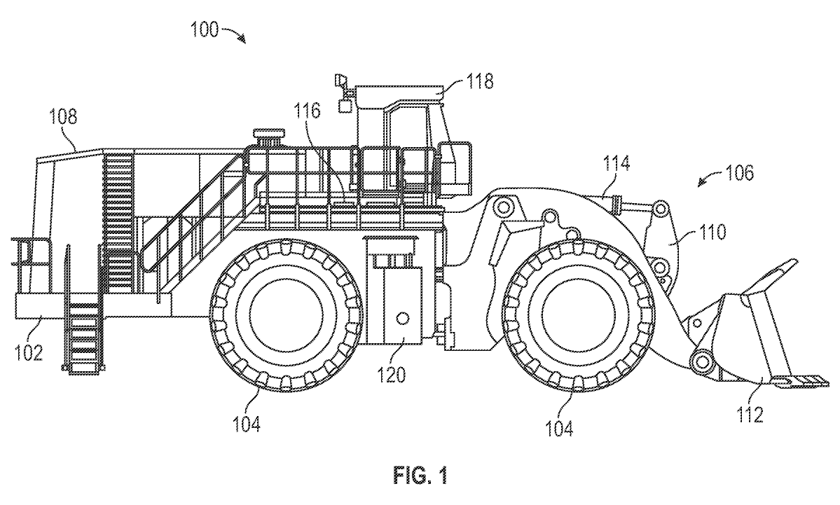

FIG. 1 depicts an example machine 100 in accordance with this disclosure. In FIG. 1, machine 100 includes frame 102, wheels 104, implement 106, and a speed control system implemented in one or more on-board electronic devices like, for example, an electronic control unit or ECU. Example machine 100 is a wheel loader. In other examples, however, the machine may be other types of machines related to various industries, including, as examples, construction, agriculture, forestry, transportation, material handling, waste management, marine, stationary power, and so on. Accordingly, although some examples are described with reference to a wheel loader machine, examples according to this disclosure are also applicable to other types of machines including graders, scrapers, dozers, excavators, compactors, material haulers like dump trucks, marine vessels, locomotives, along with other example machine types.

Machine 100 includes frame 102 mounted on four wheels 104, although, in other examples, the machine could have more than four wheels. Frame 102 is configured to support and/or mount one or more components of machine 100. For example, machine 100 includes enclosure 108 coupled to frame 102. Enclosure 108 can house, among other components, an electric motor to propel the machine over various terrain via wheels 104. In some examples, multiple electric motors are included in multiple enclosures at multiple locations of the machine 100.

Machine 100 includes implement 106 coupled to the frame 102 through linkage assembly 110, which is configured to be actuated to articulate bucket 112 of implement 106. Bucket 112 of implement 106 may be configured to transfer material such as, soil or debris, from one location to another. Linkage assembly 110 can include one or more cylinders 114 configured to be actuated hydraulically or pneumatically, for example, to articulate bucket 112. For example, linkage assembly 110 can be actuated by cylinders 114 to raise and lower and/or rotate bucket 112 relative to frame 102 of machine 100.

Platform 116 is coupled to frame 102 and provides access to various locations on machine 100 for operational and/or maintenance purposes. Machine 100 also includes an operator cabin 118, which can be open or enclosed and may be accessed via platform 116. Operator cabin 118 may include one or more control devices (not shown) such as, a joystick, a steering wheel, pedals, levers, buttons, switches, among other examples. The control devices are configured to enable the operator to control machine 100 and/or the implement 106. Operator cabin 118 may also include an operator interface such as, a display device, a sound source, a light source, or a combination thereof.

Machine 100 can be used in a variety of industrial, construction, commercial or other applications. Machine 100 can be operated by an operator in operator cabin 118. The operator can, for example, drive machine 100 to and from various locations on a work site and can also pick up and deposit loads of material using bucket 112 of implement 106. By further way of example, both operation by a remotely located operator and autonomous or robotic operation are contemplated. Machine 100 can be used to excavate a portion of a work site by actuating cylinders 114 to articulate bucket 112 via linkage assembly 110 to dig into and remove dirt, rock, sand, etc. from a portion of the work site and deposit this load in another location. Machine 100 can include a battery compartment connected to frame 102 and including a battery system 120. Battery system 120 is electrically coupled to the one or more electric motors of the electric machine 100 to power the one or more electric motors. In variations, electrical energy is provided to the electric motors from an electrical rail connected to the electric machine by a tether cable.

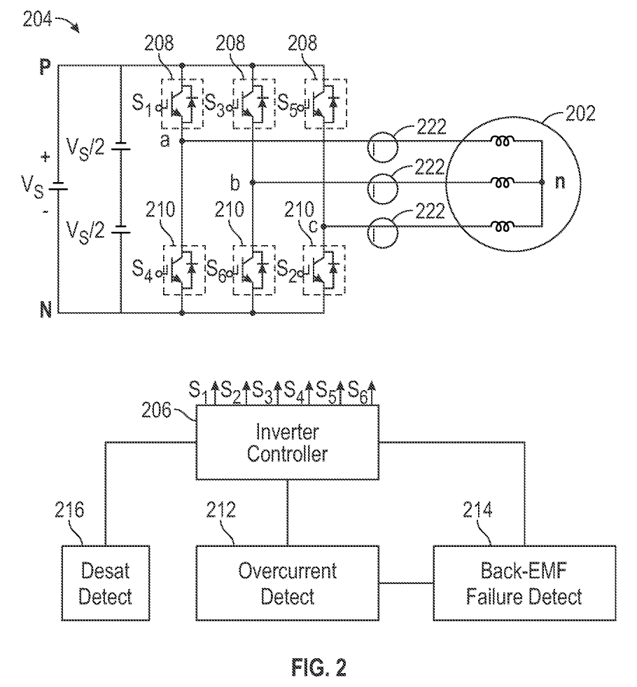

FIG. 2 is a circuit diagram of an example of portions of a switching inverter circuit 204 and a three-phase alternating current (AC) electric motor 202. The switching inverter circuit 204 consists of three inverter phase legs - one inverter leg for each phase. Each inverter leg produces an output displaced 120 degrees with respect to the other inverter legs. The switches of the inverter legs may be Insulated Gate Bipolar Transistors (IGBTs). There is a set of top IGBTs 208 and a set of bottom IGBTs 210. Switching of the IGBTs is controlled by the inverter controller 206. The inverter controller 206 includes logic circuitry to generate gate drive signals (S1, S2, … S6) for the six IGBTs. One of the two IGBTs in an inverter leg is on at any instant in normal operation of the switching inverter circuit 204. The inverter controller 206 may produce gate drive signals to switch the IGBTs according to pulse width modulation (PWM) control.

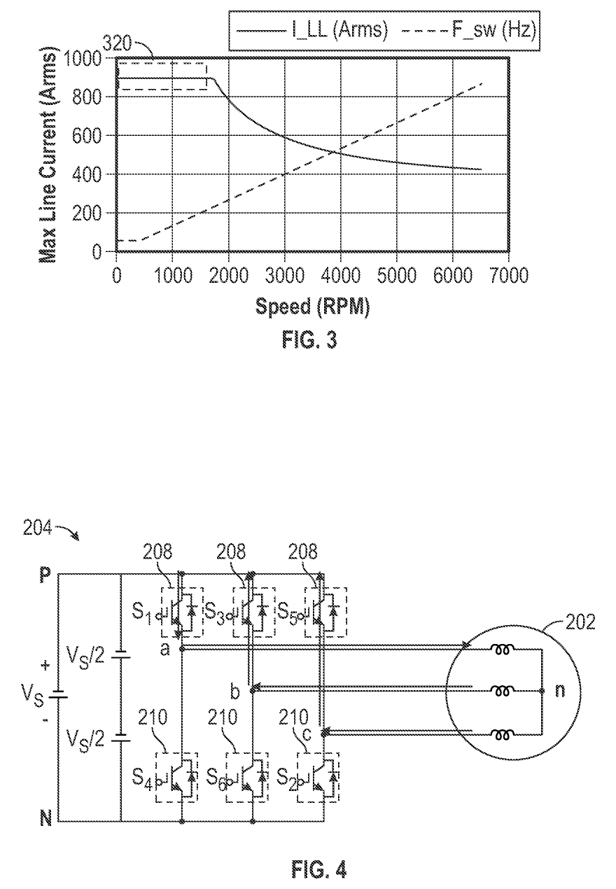

The electric motors of electric work machines are high voltage and high current. Faults in an electric motor can result in high currents that may damage components of the electrical system of the work machine. FIG. 3 is a graph of root-mean-square current (Amps rms, or Arms) versus rotor speed for an electric motor in normal operation. The graph shows an over current threshold 320. The overcurrent threshold in the normal operating mode is set to a point above the stall current of the electric motor. The example of FIG. 3 shows that the stall current can be as high as 900 Arms and the overcurrent threshold is set above 900 Arms. The overcurrent threshold is designed to limit the voltage overshoot of the IGBT module when the device is turned off at very high currents that are not within normal operating conditions. A winding short internal to the motor is an example of a failure mode that could result in high currents that trip the overcurrent protection in normal operating mode.

To address overcurrent faults in the electric motor, the circuit example in FIG. 2 includes an overcurrent detection circuit 212. The overcurrent detection circuit 212 includes one or more current sensors 222. The current sensors 222 may be included on each of the phase legs of the switching inverter circuit 204. The current sensors 222 monitor the phase currents of the inverter legs. The overcurrent detection circuit 212 detects an overcurrent event when the current sensed using the current sensor exceeds a specified current threshold. When an overcurrent event is detected, the inverter controller 206 disables the gate drive signals to the IGBTs to turn off the IGBTs and prevent damage to components of the switching inverter circuit 204 and electric motor 202.

Electric motors with an internal permanent magnet (IPM) can experience another type of fault referred to as back-EMF failure. In a back-EMF failure mode, the speed control system of the electric motor fails and the loss of speed control can cause a very large freewheeling current to occur. This freewheeling current may charge the DC bus above the maximum allowable voltage and impact components of the power system of the machine 100. An approach to protect the machine 100 from freewheeling current resulting from back-EMF failure is Active Short Circuit (ASC). In the event of a high speed back-EMF failure fault, either all the top IGBTs 208 or all the bottom IGBTs 210 are turned on as an active short circuit to provide a path for the current without charging the DC bus. This activation of the IGBTs in the ASC mode overrides the switching of the IGBTs according to PWM in the first operating mode.

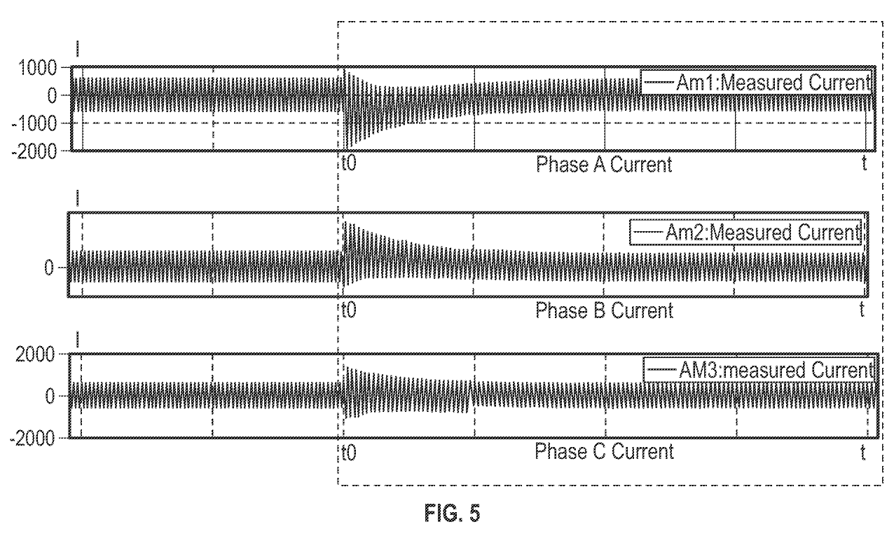

FIG. 4 shows the top set of IGBTs 208 activated to short the freewheeling current to the DC bus in the ASC mode. Only one of the sets of top IGBTs 208 or bottom IGBTs 210 are turned on. The top and bottom IGBTs should not be turned on at the same time. FIG. 5 is an illustration of examples of phase current transients when the switching inverter circuit 204 enters ASC mode. The three waveforms correspond to the phases shown as phase a, b, c in FIG. 4. The waveforms show the peak current that can occur at time t0 when the inverter controller activates IGBTs for ASC mode. The peak current depends on motor speed and the peak will increase with motor speed. FIG. 5 shows that the transient current waveforms are asymmetric and the waveforms will vary depending on position of the rotor when ASC mode is activated. The peak current transients create high power loss on the circuit die of the inverter IGBT 208. The three phases will be stressed differently due to the asymmetric transient current waveform. The waveforms show that the peak current transients can reach nearly 2000 Amps (2000A) in ASC mode.

Returning to FIG. 2, the switching inverter circuit 204 includes a back-EMF failure detection circuit 214. The back-EMF failure detection circuit 214 may be integrated with the inverter controller 206 and internal to the switching inverter circuit 204. In certain examples, the back-EMF failure detection circuit 214 may be included in an ASC control circuit that detects the back-EMF failure and overrides the switching of the IGBTs by the inverter controller 206.

The back-EMF failure detection circuit 214 includes a speed sensor to monitor the speed of the rotor of the electric motor 202. The back-EMF failure detection circuit 214 also includes a voltage sensor to detect overvoltage when voltage of a DC bus connected to the switching inverter circuit 204 exceeds a specified overvoltage detection threshold. The back-EMF failure detection circuit 214 detects high speed back-EMF failure when the speed sensor detects that the rotor speed exceeds a threshold speed (e.g., 3750 revolutions per minute or 3750 rpms) and a failure resulting in loss of motor control is detected. The back-EMF failure detection circuit 214 activates its output and the inverter controller 206 enters ASC mode by activating all the top IGBTs 208 or activating all the bottom IGBTs 210.

There is also an overcurrent threshold in the ASC mode above which the IGBTs should be turned off. The overcurrent turnoff threshold in the ASC mode has a different requirement from the overcurrent turn off threshold in the normal switching mode. Turning the IGBTs off at too low a current threshold in the ASC mode would not enable the path through the top or bottom IGBTs for the freewheeling current to flow. Turning off the IGBTs at too high a current threshold in the normal switching mode may stress components of the switching inverter circuit 204 and electric motor 202.

The overcurrent detection circuit 212 monitors for two overcurrent thresholds. The overcurrent detection circuit 212 detects overcurrent using a first lower overcurrent threshold value (e.g., 1600A) when the inverter controller 206 is operating in the normal IGBT switching mode and changes to detecting overcurrent using a second greater overcurrent threshold value (e.g., 2000A) when the inverter controller 206 is operating in the ASC mode after a high speed back-EMF failure is detected. When overcurrent is detected either in the normal mode or the ASC mode, the inverter controller 206 disables the gate drive signals to the IGBTs (top and bottom) of the switching inverter circuit 204. In an illustrative example intended to be non-limiting, the overcurrent detection threshold circuit 212 may include a resistive divider circuit to generate a voltage from the current being monitored and compares the generated voltage to a detection voltage to detect overcurrent. The resistive values of the resistive divider are changed when the inverter controller enters the ASC mode to change the detection voltage for overcurrent detection.

In some examples, the switching inverter circuit 204 includes a desaturation detection circuit 216 configured to detect when one or more of the IGBTs operate in a desaturation (DESAT) mode. The desaturation detection circuit 216 may include one or more voltage sensors to monitor collector-to-emitter voltages of the IGBTs to detect when an IGBT enters desaturation mode. Detection of a desaturation fault and an overcurrent fault using the greater overcurrent threshold in the ASC mode triggers the inverter controller to perform a safe turnoff and disable the gate drive signals to the IGBTs.

When the inverter controller 206 enters ASC mode, the inverter controller 206 stays in ASC mode until the back-EMF failure detection circuit 214 no longer indicates high speed back-EMF failure and the inverter controller 206 is reset. When high speed back-EMF failure is no longer indicated, the inverter controller 206 may return to normal operating IGBT switching mode and may switch the IGBTs using PWM to operate the switching inverter circuit 204 or switch the IGBTs according to a different switching algorithm and return to using the first lower overcurrent detection threshold to detect overcurrent.

The overcurrent fault detection using the two overcurrent detection thresholds protects the power circuitry of the switching inverter circuit 204 and the electric motor 202 from voltage overshoot of the IGBTs while still providing Active Short Circuit protection to resolve freewheeling currents in the event of back-EMF failure.

### Industrial Applicability

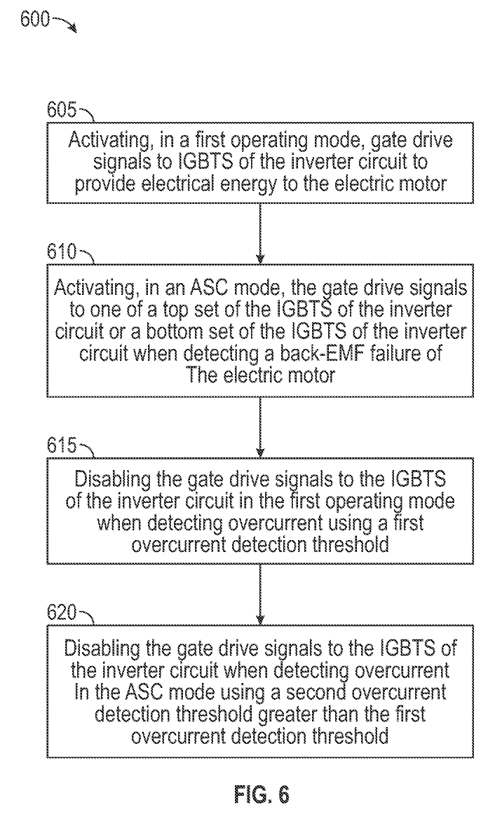

FIG. 6 is a flow diagram of an example of a method 800 of operating a switching inverter circuit of an electric motor. The method 600 may be performed using the three phase switching inverter circuit 204 example of FIG. 2 that includes an inverter controller 206. The method 600 may also be performed using other types of power converters and control circuits for the power converters.

At block 605, the inverter controller activates switching devices of the inverter circuit according to a first operating mode that is a normal operating switching mode. The inverter circuit includes top switching devices operatively coupled to the electric motor and a high or positive supply rail, and bottom switching devices coupled to the electric motor the top switching devices and a low or negative supply rail. The switching devices may be IGBTs and the inverter controller may switch the IGBTs to provide electrical energy to the electric motor according to PWM switching.

At block 610, the inverter controller enters ASC mode in response to detection of a high speed back-EMF failure of the electric motor. The high speed back-EMF failure may be detected by a voltage on a DC bus exceeding a specified overvoltage detection threshold or the rotor speed of the electric motor exceeding a specified speed detection threshold and machine control is lost. In the ASC mode, the inverter controller activates either the top IGBTs (as in FIG. 4) or the bottom IGBTs to keep freewheeling current associated with back-EMF failure from charging the DC bus to a high voltage.

At block, 615, the inverter controller disables the gate signals to all the IGBTs when it is operating in the first operating mode and a current of the electric motor (e.g., one of the phase currents of the electric motor) is sensed that exceeds a first overcurrent detection threshold. The overcurrent detection threshold is changed when the inverter controller changes to operating in the ASC mode. The overcurrent detection threshold is changed to a second overcurrent detection threshold greater than the first overcurrent threshold when the inverter controller changes to operating in the ASC mode.

At block 620, the inverter controller disables the gate drive signals to deactivate the IGBTs of the inverter circuit in the ASC mode when detecting overcurrent using the second higher overcurrent detection threshold to perform a safe turnoff of all IGBTs. In variations, the inverter controller disables the gate drive signals to deactivate the IGBTs of the inverter circuit in the ASC mode when detecting the overcurrent level and desaturation of one or more of the IGBTs activated in the ASC mode.

The inverter controller may reactivate the IGBTs used in the ASC mode when the sensed current decreases below the second higher overcurrent detection threshold and the back-EMF failure remains detected to keep the inverter controller operating in the ASC mode. When the high speed back-EMF failure is no longer detected, the inverter controller may end operating in the ASC mode when the inverter controller is reset. The inverter controller may resume operating in the normal switching mode. Changing operating modes changes the overcurrent detection back to the lower overcurrent detection level. If the sensed current is greater than the lower overcurrent detection level, the inverter controller may again disable the IGBTs. If the sensed current is lower than the lower overcurrent detection level the inverter controller may return to switching the IGBTs in the normal switching mode to provide electrical energy to the electric motor.

Unless explicitly excluded, the use of the singular to describe a component, structure, or operation does not exclude the use of plural such components, structures, or operations or their equivalents. The use of the terms “a” and “an” and “the” and “at least one” or the term “one or more,” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B” or one or more of A and B”) is to be construed to mean one item selected from the listed items (A or B) or any combination of two or more of the listed items (A and B; A, A and B; A, B and B), unless otherwise indicated herein or clearly contradicted by context. Similarly, as used herein, the word "or" refers to any possible permutation of a set of items. For example, the phrase "A, B, or C" refers to at least one of A, B, C, or any combination thereof, such as any of: A; B; C; A and B; A and C; B and C; A, B, and C; or multiple of any item such as A and A; B, B, and C; A, A, B, C, and C; etc.

The above detailed description is intended to be illustrative, and not restrictive. The scope of the disclosure should, therefore, be determined with references to the appended claims, along with the full scope of equivalents to which such claims are entitled.

What is claimed is:

1. A switching inverter circuit for an electric motor, the circuit comprising:
a set of top insulated gate bipolar transistors (IGBTs) and a set of bottom IGBTs configured to provide energy to the electric motor;
an overcurrent detection circuit;
a back electromotive force (back-EMF) failure detection circuit;
an inverter controller configured to:
produce gate drive signals to switch the set of top IGBTs and the set of bottom IGBTs according to pulse width modulation (PWM) in a first operating mode;
disable the gate drive signals in response to the overcurrent detection circuit detecting overcurrent that exceeds a first overcurrent threshold in the first operating mode;
produce the gate drive signals to activate one of all the top set of IGBTs or all the bottom set of IGBTs in an Active Short Circuit (ASC) mode when a high speed back electromotive force (back-EMF) failure is detected; and
disable the gate drive signals to the IGBTs of the inverter circuit in response to the overcurrent detection circuit detecting an overcurrent level that exceeds a second overcurrent detection threshold greater than the first overcurrent detection threshold.

2. The circuit of claim 1, including three phase legs to provide phase currents to the electric motor, and wherein the overcurrent detection circuit is configured to detect overcurrent in one or more of the three phase legs.

3. The circuit of claim 1, wherein the inverter controller is configured to:
produce the gate drive signals to reactivate the one of the top set of the IGBTs of the inverter circuit or the bottom set of the IGBTs of the inverter circuit when in the ASC mode and the detected overcurrent decreases below the second overcurrent detection threshold and the high speed back-EMF failure is detected.

4. The circuit of claim 1, wherein the inverter controller is configured to:
change from operating in the ASC mode to operating in the first operating mode when the high speed back-EMF failure is no longer detected and the inverter controller is reset.

5. The circuit of claim 4, wherein the inverter controller is configured to:
change from disabling the IGBTs using the second overcurrent detection threshold to disabling the IGBTs using the first overcurrent detection threshold when the high speed back-EMF failure is no longer detected and the inverter controller is reset.

6. The circuit of claim 1, wherein the inverter controller is configured to produce the gate drive signals to activate one of all the top set of IGBTs or all the bottom set of IGBTs in the ASC mode when sensed current is less than the second overcurrent threshold.

7. The circuit of claim 1, wherein the back-EMF failure detection circuit includes a voltage sensor configured to detect when voltage of a DC bus connected to the IGBTs exceeds a specified overvoltage detection threshold or a speed sensor that is configured to detect when a rotor speed of the electric motor exceeds a specified speed detection threshold and machine control is lost.

8. The circuit of claim 1, including:
a desaturation detection circuit configured to detect operation of the IGBTs in a desaturation mode; and
wherein the inverter controller is configured to disable the gate drive signals to deactivate the IGBTs in the ASC operating mode when detecting a desaturation fault and the overcurrent greater than the second overcurrent threshold.

9. A method of operating a switching inverter circuit of an electric motor, the method comprising:
activating, in a first operating mode, gate drive signals to insulated gate bipolar transistors (IGBTs) of the inverter circuit to provide electrical energy to the electric motor;
activating, in an Active Short Circuit (ASC) mode, the gate drive signals to one of a top set of the IGBTs of the switching inverter circuit or a bottom set of the IGBTs of the switching inverter circuit when detecting a back electromotive force (back-EMF) failure of the electric motor;
disabling the gate drive signals to the IGBTs of the switching inverter circuit in the first operating mode when detecting overcurrent using a first overcurrent detection threshold; and
disabling the gate drive signals to the IGBTs of the switching inverter circuit in the ASC mode when detecting overcurrent using a second overcurrent detection threshold greater than the first overcurrent detection threshold.

10. The method of claim 9, wherein the detecting the overcurrent includes detecting the overcurrent on inverter phase legs of the switching inverter circuit.

11. The method of claim 9, including:
changing from operating in the ASC mode to operating in the first operating mode when the back-EMF failure is no longer detected and resetting an inverter controller is reset.

12. The method of claim 11, including:
returning to disabling the gate drive signals in the first operating mode using the first overcurrent detection threshold when the back-EMF failure is no longer detected and resetting an inverter controller.

13. The method of claim 9, including:
returning to activating the one of the top set of the IGBTs of the inverter circuit or the bottom set of the IGBTs of the inverter circuit when in the ASC mode and sensed current decreases to less than the second overcurrent detection threshold and the back-EMF failure is detected.

14. The method of claim 9, wherein the activating one of all the top set of IGBTs or all the bottom set of IGBTs in the ASC mode includes activating when sensing current less than the second overcurrent threshold.

15. The method of claim 9,
wherein disabling the IGBTs in the ASC mode includes disabling the gate drive signals to the IGBTs of the inverter circuit when detecting the overcurrent using the second overcurrent detection threshold and detecting desaturation of the IGBTs.

16. A fault-detection circuit for a switching inverter circuit of an electric motor, the fault-detection circuit comprising:
an overcurrent detection circuit;
a back electromotive force (back-EMF) failure detection circuit;
a control circuit configured to:
disable gate drive signals produced by the switching inverter circuit in response to the overcurrent detection circuit detecting overcurrent that exceeds an overcurrent detection threshold of a first current value, wherein the gate drive signals drive insulated gate bipolar transistors (IGBTs) that provide power to the electric motor; and
enable gate drive signals to activate one of a top set of IGBTs or a bottom set of IGBTs in an Active Short Circuit (ASC) mode in response to detection of a back electromotive force (back-EMF) failure and change the overcurrent detection threshold to a second overcurrent value greater than the first current value when in the ASC mode.

17. The fault-detection circuit of claim 16, wherein the control circuit is configured to:
enable the gate drive signals to activate the top set of IGBTs or the bottom set of IGBTs when sensed current is less than the second overcurrent value when in the ASC mode and the back-EMF failure is detected; and
disable the gate drive signals to activate the top set of IGBTs or the bottom set of IGBTs in response to the overcurrent detection circuit detecting overcurrent greater than the second overcurrent value when in the ASC mode.

18. The fault-detection circuit of claim 16, wherein the control circuit is configured to:
re-enable the gate drive signals to activate the top set of IGBTs or the bottom set of IGBTs when sensed current decreases to less than the second overcurrent value in the ASC mode.

19. The fault-detection circuit of claim 16,
wherein the back-EMF failure detection circuit is configured to detect an overvoltage fault for the switching inverter circuit or a loss of motor control when a rotor speed of the electric motor exceeds a specified threshold speed.

20. The fault-detection circuit of claim 16, including:
a desaturation detection circuit configured to detect when one or more of the IGBTs operate in a desaturation mode; and
wherein the control circuit is configured to disable the gate drive signals to the IGBTs of the switching inverter circuit in the ASC mode when detecting a desaturation fault and the overcurrent greater than the second overcurrent threshold.
